(19) United States
(12) Patent Application Publication
(10) Pub. No.: US 2005/0236626 A1
(43) Pub. Date: Oct. 27, 2005

(54) Semiconductor device, producing method of semiconductor substrate, and producing method of semiconductor device

(75) Inventors: Yutaka Takafuji, Nara-shi (JP); Takashi Itoga, Nara-shi (JP); Steven R. Droes, Camas, WA (US); Masao Moriguchi, Tenri-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/088,252

(22) Filed: Mar. 24, 2005

(30) Foreign Application Priority Data
Mar. 24, 2004 (JP) 2004-087914

(51) Int. Cl. H01L 21/00; H01L 29/04

(52) U.S. Cl. 257/70; 257/413; 438/30; 438/592

(57) ABSTRACT

In a semiconductor device including an insulative substrate and a thin film device formed thereon, a thin film transistor having a non-single crystalline silicon thin film and a transistor having a single crystalline silicon thin film are intermixed, and a gate electrode film of the thin film transistor having single crystalline silicon is made of a material including a metal whose mass number is larger than that of silicon or a compound containing the metal.

This Nonprovisional application claims priority under 35 U.S.C. § 119(a) on Patent Application No. 087914/2004 filed in Japan on Mar. 24, 2004, the entire contents of which are hereby incorporated by reference.

### FIELD OF THE INVENTION

The present invention relates to a semiconductor device designed to improve the circuit performance of a liquid crystal display device integrating a peripheral drive circuit and a control circuit and so on onto the same substrate in an active-matrix-liquid crystal display device driven by a TFT, a producing method thereof, and a single crystalline silicon substrate used to produce the semiconductor device.

### BACKGROUND OF THE INVENTION

Conventionally, a display device has been used which, including a glass substrate and a thin film transistor (hereinafter referred to as a TFT) of amorphous silicon (hereinafter abbreviated as a-Si) or polycrystalline silicon (hereinafter abbreviated as p-Si formed thereon, drives a liquid-crystal display panel, an organic EL (electroluminescence) panel, or the like, i.e., carries out active matrix drive.

Particularly, a display device has come to be used which integrates a peripheral driver by using p-Si having high mobility and operating at a high speed. However, for the purpose of system integration of an image processor, a timing controller, and the like, which are demanded for higher performance, a silicon device with higher performance is required.

This is because there is the problem that a polycrystalline silicon transistor does not have sufficient performance to provide a high-performance silicon device. The problem results from localized state in the energy gap caused by crystal imperfections, defects around a crystal grain boundary, a decrease in electron (or hole) mobility caused by localized state in the energy gap, and an increase in subthreshold coefficient.

Accordingly, in order to produce a silicon device with higher performance, a technique has been studied by which a semiconductor device is produced by adhering onto an insulative substrate a preformed device such as a thin film transistor formed of a single crystalline silicon thin film (e.g., see Japanese Laid-Open Patent Publication No. 503557/1995 (Tokuhyohei 7-503557; published on Apr. 13, 1995: WO93/15589), J. P. Salerno “Single Crystal Silicon AMLCDs”, Conference Record of the 1994 International Display Research Conference (IDRC) P. 39-44 (1994), and Q.-Y. Tong & U. Gesele, SEMICONDUCTOR WAFER BONDING: SCIENCE AND TECHNOLOGY, John Wiley & Sons, New York (1999)).

Japanese Laid-Open Patent Publication No. 503557/1995 discloses a technique for producing a display panel of an active-matrix liquid crystal display device by using a semiconductor device including a glass substrate and a previously prepared single crystalline-silicon thin film transistor transferred thereonto with an adhesive agent.

Further, Japanese Patent No. 3048201 (published on Aug. 20, 1993: Corresponding U.S. Pat. No. 5,374,564) discloses a technique for peeling thin-film single crystalline silicon from a single crystalline silicon substrate not having a thin film transistor by heat treatment, after implantation of a hydrogen ion of predetermined concentration at a predetermined depth in a single crystalline silicon layer.

Further, Japanese Laid-Open Patent Publication No. 106424/2000 (Tokukai 2000-106424; published on Apr. 11, 2000: Corresponding U.S. Pat. No. 6,271,101) discloses a technique for forming a transistor on thin-film single crystalline silicon which has been peeled from a single crystalline silicon substrate not having a thin film transistor. That is, Japanese Laid-Open Patent Publication No. 106424/2000 discloses a technique which includes the steps of: (i) forming an insulation film on one surface of a single crystalline silicon substrate; (ii) patterning an silicon oxide film; (iii) converting a portion of the single crystalline silicon substrate without the silicon oxide film into a porous layer by an anode conversion treatment; (iv) adding a hydrogen ion across a layer where both a single crystalline silicon layer and a porous layer are provided, from a main surface; (v) bonding the single crystalline silicon substrate to a separate substrate provided with an oxide silicon film thereon; (vi) heating at about 500° C., thereby separating the single crystalline silicon substrate from the hydrogen-added layer and forming thin-film single crystalline silicon on the separate substrate; and (vii) performing a further process with respect to the thin-film single crystalline silicon to form a thin film transistor on the separate substrate.

Because a hydrogen ion is used to peel a single crystalline silicon substrate before a transistor is formed on the single crystalline silicon substrate in both Japanese Patent No. 3048201 and Japanese Laid-Open Patent Publication No. 106424/2000, the following problem has never occurred.

That is, when a hydrogen ion is implanted into an entire surface of a single crystalline silicon substrate provided with a single crystalline silicon thin film transistor thereon, a hydrogen ion and a helium ion are implanted into a channel section of a transistor, thereby causing a slight crystal lattice defect or causing a hydrogen atom of high concentration to form a complex with Boron to deactivate. As a result, this has incurred a transistor characteristic deterioration in that a threshold value of a transistor shifts to a negative side.

Further, it has been extremely difficult to apply a glass substrate in consideration of a case where a thin film transistor formed of single crystalline silicon is transferred onto the glass substrate. This is because a heat treatment at a temperature much higher than a heat-resistant temperature of the glass substrate is required in order to form a transistor on a single crystalline silicon thin film.

### SUMMARY OF THE INVENTION

It is an object of the present invention to provide an arrangement capable of preventing a characteristic deterioration of a single crystalline silicon thin film transistor in a semiconductor device which transfers the single crystalline silicon thin film transistor onto an insulative substrate such as glass.

In order to solve the foregoing problems, a semiconductor device of the present invention is arranged so that a gate electrode of a single crystalline silicon thin film transistor is made of a material including (i) an element whose average atomic number is 28 or larger, (ii) an element whose density is 10 g/cm³ or higher, (iii) a compound containing the element (i), or (iv) a compound containing the element (ii), the single crystalline silicon thin film transistor having a source, a drain, and a channel region provided in single crystalline silicon.

Alternatively, the semiconductor device of the present invention is a semiconductor device including an insulative substrate and a thin film device formed thereon, wherein: a non-single crystalline silicon thin film transistor and a single crystalline silicon thin film are provided together, the non-single crystalline silicon thin film transistor having a source, a drain, and a channel region provided in non-single crystalline silicon, the single crystalline silicon thin film transistor having a source, a drain, and a channel region provided in single crystalline silicon, and a gate electrode of the single crystalline silicon thin film transistor is made of a material including (i) an element whose average atomic number is 28 or larger, (ii) an element whose density is 10 g/cm³ or higher, (iii) a compound containing the element (i), or (iv) a compound containing the element (ii).

With the foregoing arrangement, a hydrogen ion or a helium ion can be prevented from passing through a gate layer, so that a silicon-gate insulator film interface and the channel region under the gate electrode are protected from damage.

Note that the semiconductor device of the present invention is desired to include no continuous pattern of 2 μm or more per side in lateral and longitudinal directions. This is because it is considered that with a gate pattern including a continuous region of about less than 2 μm per side in both of the two directions, cleavage failure in an area under the gate electrode can be avoided for a slight lateral cleavage and a laterally distributed ion.

Further, in order to solve the foregoing problems, a method of the present invention for producing a semiconductor device is a method for producing a semiconductor substrate including a single crystalline silicon substrate and a gate electrode formed thereon with a gate insulator film interposed therebetween, the method including the steps of: forming a surface protection film on a region serving as a transistor including the gate electrode; and implanting a hydrogen ion and/or a helium ion of predetermined concentration into the single crystalline silicon substrate, wherein: a combination of conditions an implantation energy of a hydrogen ion and/or a helium ion, a material for the gate electrode, and a film thickness of the surface protection film is set so that a projection range of a hydrogen ion and/or a helium ion is equal to or less than a total film thickness of the gate electrode and the surface protection film in a region where the gate electrode is formed, and so that a projection range of a hydrogen ion and/or a helium ion is more than the total film thickness of the gate electrode and the surface protection film in a region where the gate electrode is not formed.

With the foregoing arrangement, when a hydrogen ion and/or a helium ion are/is implanted into a silicon layer, a projection range of a hydrogen ion and/or a helium ion becomes equal to or less than a total film thickness of the gate electrode and the surface protection film in a region where the gate electrode is formed. This prevents a transistor characteristic deterioration caused when a hydrogen ion or a helium ion is implanted into a channel section (i.e., a section under a gate electrode) of a transistor.

Note that implantation of a hydrogen ion and/or a helium ion into the single crystalline silicon substrate is not limited to implantation of either a hydrogen ion or a helium ion, but also includes implantation of both a hydrogen ion and a helium ion.

Further, in order to solve the foregoing problems, another method of the present invention for producing a semiconductor device is a method for producing a semiconductor substrate including a single crystalline silicon substrate and a gate electrode formed thereon with a gate insulator film interposed therebetween, the method including the steps of: forming a surface protection film on a region serving as a transistor including the gate electrode; and implanting a hydrogen ion and/or a helium ion of predetermined concentration into a single crystalline silicon substrate more than once, the hydrogen ion and/or helium ion implantation step including: a first implantation step in which a combination of conditions of an implantation energy of a hydrogen ion and/or a helium ion, a material for the gate electrode, and a film thickness of the surface protection film is determined so that a projection range of a hydrogen ion and/or a helium ion is equal to or less than a total film thickness of the gate electrode and the surface protection film in a region where the gate electrode is formed, and so that a projection range of a hydrogen ion and/or a helium ion is more than the total film thickness of the gate electrode and the surface protection film in a region where the gate electrode is not formed; and a second implantation step of implanting a hydrogen ion and/or a helium ion at lower ion implantation dose than in the first implantation step, wherein an implantation energy is set so that, in the region where the gate electrode is formed, an implantation peak position of a hydrogen ion and/or a helium ion passing through the gate electrode and the gate insulator film becomes equal to an implantation peak position of a hydrogen ion and/or a helium ion passing through the surface protection film and gate insulator film at the time of ion implantation in the first implantation step.

With the foregoing arrangement, when a hydrogen ion and/or a helium ion are/is implanted into a silicon layer in the first ion implantation step, a projection range of a hydrogen ion and/or a helium ion becomes equal to or less than a total film thickness of the gate electrode and the surface protection film in a region where the gate electrode is formed. This prevents a transistor characteristic deterioration caused when a hydrogen ion or a helium ion is implanted into a channel section (i.e., a section under a gate electrode) of a transistor.

Further, in the second ion implantation step, an implantation peak position of an ion implanted into an underside of the gate electrode becomes equal to that of a hydrogen ion and/or a helium ion implanted through the surface protection film and the gate oxide film in the first ion implantation step, and therefore helps cleave and separate the underside of the gate electrode, thereby improving the flatness of the silicon film which has been cleaved and separated.

Note that the first ion implantation step may precede or follow the second ion implantation step.

Further, in order to solve the foregoing problems, a further method of the present invention for producing a semiconductor device is a method for producing a semiconductor substrate including a single crystalline silicon substrate and a gate electrode formed thereon with a gate insulator film interposed therebetween, the method including the steps of: forming a planarization insulator film thicker than the gate electrode on a region serving as a transistor including the gate electrode; and implanting a hydrogen ion and/or a helium ion of predetermined concentration into the single crystalline silicon substrate after planarization of the planarization insulator film, wherein: a combination of conditions of an implantation energy of a hydrogen ion and/or a helium ion, a material for the gate electrode, and a film thickness of the planarization insulator film is set so that a projection range of a hydrogen ion and/or a helium ion is equal to or less than a total film thickness of the gate electrode and the planarization insulator film in a region where the gate electrode is formed and so that a projection range of a hydrogen ion and/or a helium ion is more than the total film thickness of the gate electrode and the planarization insulator film in a region where the gate electrode is not formed.

With the foregoing arrangement, when a hydrogen ion and/or a helium ion are/is implanted into a silicon layer, a projection range of a hydrogen ion and/or a helium ion becomes equal to or less than a total film thickness of the gate electrode and the planarization insulator film in a region where the gate electrode is formed. This prevents a transistor characteristic deterioration caused when a hydrogen ion or a helium ion is implanted into a channel section of a transistor. Further, planarization of a perimeter of the gate electrode before ion implantation decreases ununiformity in distribution of implanted hydrogen ions of high concentration, thus improving the flatness of the silicon thin film being cleaved and separated.

For a fuller understanding of the nature and advantages of the invention, reference should be made to the ensuing detailed description taken in conjunction with the accompanying drawings.

### BRIEF DESCRIPTION OF THE DRAWINGS

FIGS. 1(a) to 1(c) are cross-sectional views showing one embodiment of the present invention and showing a process of producing a semiconductor device according to the First Embodiment.

FIG. 2 is a cross-sectional view showing a structural example of the semiconductor device according to the present invention.

FIG. 3 is a graph showing a relationship between a projection range per energy of a hydrogen ion and a helium ion and an atomic number of a material into which an ion is implanted.

FIG. 4 is a graph showing a relationship between a projection range per energy of a hydrogen ion and a helium ion and a density of a material into which an ion is implanted.

FIGS. 5(a) to 5(c) are cross-sectional views showing a process of producing the semiconductor device according to the Second Embodiment.

FIGS. 6(a) to 6(c) are cross-sectional views showing a process of producing the semiconductor device according Third Embodiment.

### DESCRIPTION OF THE EMBODIMENTS

The embodiments of the present invention will be described below with reference to the drawings.

### First Embodiment

One embodiment of the present invention will be described below with reference to the drawings.

A semiconductor device described in the present embodiment is a semiconductor device, including an insulative substrate provided with both a non-single crystalline silicon-based thin film transistor and a single crystalline silicon-based thin film transistor thereon, which is suitable to high performance and high sophistication. Described below as one example of the semiconductor device is a case where an active matrix substrate with a TFT is formed by using an MOS-type transistor as a non-single crystalline silicon transistor and a single crystalline silicon transistor.

An MOS-type thin film transistor is a general transistor which is formed of an active semiconductor layer, a gate electrode, a gate insulator film, and a high-concentration impurity doped section (source/drain region) formed on both sides of a gate, the gate electrode modulating carrier concentration of a semiconductor layer under the gate electrode to control a current flowing between the source and the drain.

An MOS-type transistor is suitable for a low power consumption logic in that, when in a CMOS (complementary MOS) structure, the MOS-type transistor consumes low electric power and can fully swing an output according to a power supply voltage.

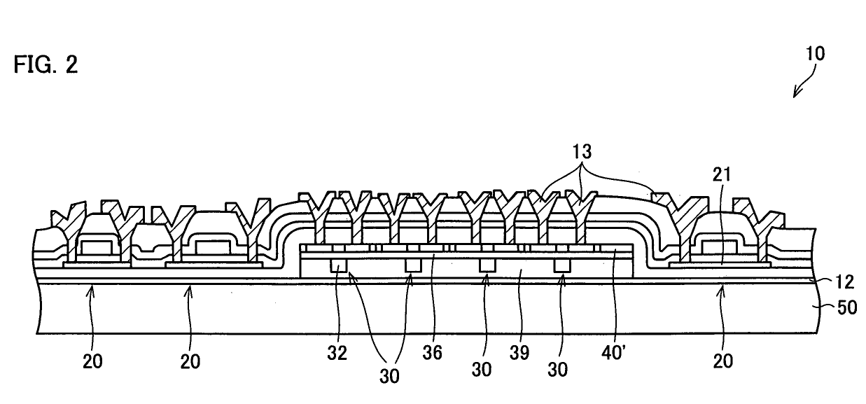

As shown in FIG. 2, a semiconductor device 10 according to the First Embodiment has an insulative substrate 50 provided with an SiO₂ film 12, an MOS-type non-single crystalline silicon thin film transistor 20 including a non-single crystalline silicon thin film 21 formed of polycrystalline silicon, an MOS-type single crystalline silicon thin film transistor (single crystalline silicon thin film device) 30 having a single crystalline silicon thin film 40′, and a metal wiring 13 thereon.

The insulative substrate 50 is formed of high strain point glass. One example is code 1737 (alkaline earth-aluminosilicate glass) manufactured by Corning Incorporated. The SiO₂ film 12 with a film thickness of 50 nm is formed on an entire surface of the insulative substrate 50.

The MOS-type single crystalline silicon thin film transistor 30 including the single crystalline silicon thin film 40′ has a gate electrode 32, a planarization film 39, an SiO₂ film 36 serving as a gate insulator film, and the single crystalline silicon thin film 40′.

As described above, the semiconductor device 10 of the present embodiment can provide a high-performance and high-sophistication semiconductor device, which integrates a plurality of circuits with different characteristics, by causing the MOS-type non-single crystalline silicon thin film transistor 20 and the MOS-type single crystalline silicon thin film transistor 30 to coexist on the insulative substrate 50. Further, a high-performance and high-sophistication semiconductor device can be obtained at lower cost than a semiconductor device including one insulative substrate 50 and transistors thereon all of which are formed of a single crystalline silicon thin film.

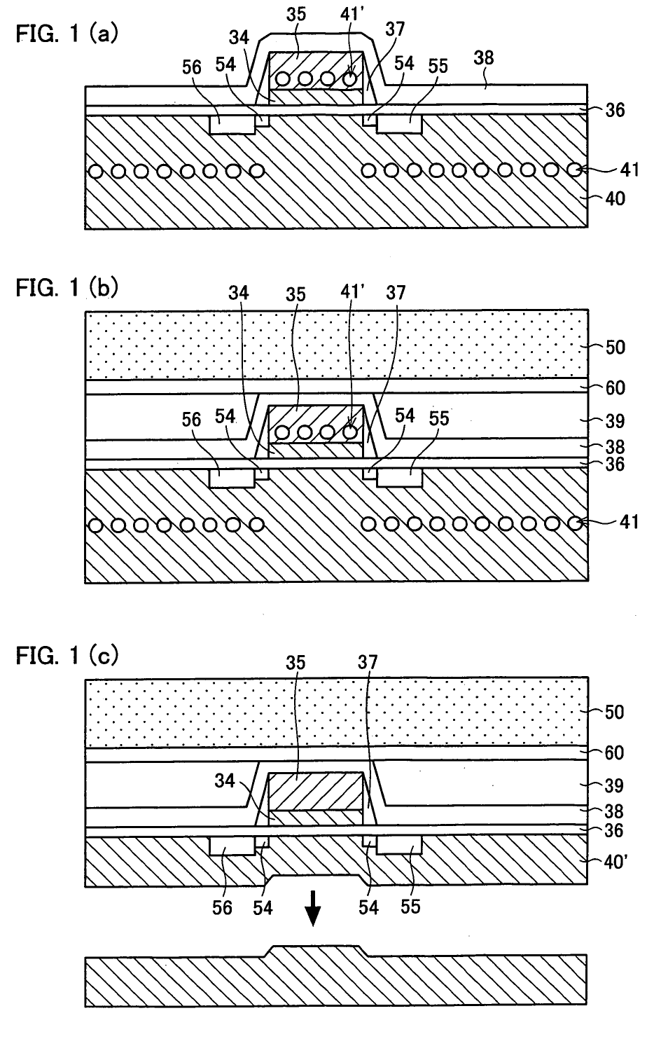

Such a semiconductor device 10 is formed through a first process for forming the single crystalline silicon thin film transistor 30 on the insulative substrate 50 and a second step of forming the non-single crystalline silicon thin film transistor 20. Accordingly, the first step will be described first with reference to FIGS. 1(a) to 1(c) and FIG. 2, and the second step will be described then with reference to FIG. 2.

First, the steps up to a state shown in FIG. 1(a) will be described. A single crystalline silicon wafer (single crystalline silicon substrate) 40 is cleaned by a general cleaning method (e.g., by which a natural oxide film is removed with dilute hydrofluoric acid, and a particle, organic matter, and the like are removed by SC1 and SC2 cleaning agents).

Next, an oxide film for element separation and the gate insulator film 36 are formed in a predetermined region by a thermal oxidation method. The gate insulator film 36 has a thickness of 5 to 50 nm. The oxidation method is for example a pyrogenic oxidation method or an HCl oxidation method.

Next, an impurity (phosphorous or boron) for threshold control is implanted into the single crystalline silicon wafer 40.

Then, a gate electrode material with a thickness of about 200 to 400 nm is formed on the gate insulator film 36. The gate electrode material is formed of a double layer constituted of a gate electrode film 35 and a polycrystalline silicon film 34. The gate electrode film 35 includes a metal, such as tungsten, whose atomic number is large, a silicide of the metal, or both of the materials. Here, a gate electrode film with a film thickness of about 300 nm was formed on n⁺ polycrystalline silicon with a film thickness of about 50 nm by sputtering.

It is important that the gate electrode film 35 is formed not of polysilicon used in a general process but of a material including a material whose average atomic number is 28 or larger or whose density is 10 g/cm³ or higher. It is for the following reason that a material whose average atomic number or average density is large is thus used as the gate electrode film 35.

As described later, in order to thin a transistor which has been formed on the single crystalline silicon, a technique is used by which a hydrogen ion or a helium ion is implanted into the single crystalline silicon and a heat treatment is performed to cleave and peel the single crystalline silicon by a hydrogen ion or helium ion implantation layer in the single crystalline silicon. When a hydrogen ion or a helium ion is implanted by the technique, a hydrogen ion or a helium ion passing through a channel section under the gate electrode 32 causes a defect in the channel section, thereby deteriorating a transistor characteristic.

Accordingly, in order to prevent a hydrogen ion or a helium ion from passing through the channel section, a projection range of an implanted hydrogen ion or helium ion must be arranged so as to be equal to or less than a total film thickness of a gate electrode and a surface protection film. This prevents a defect from occurring in the channel section.

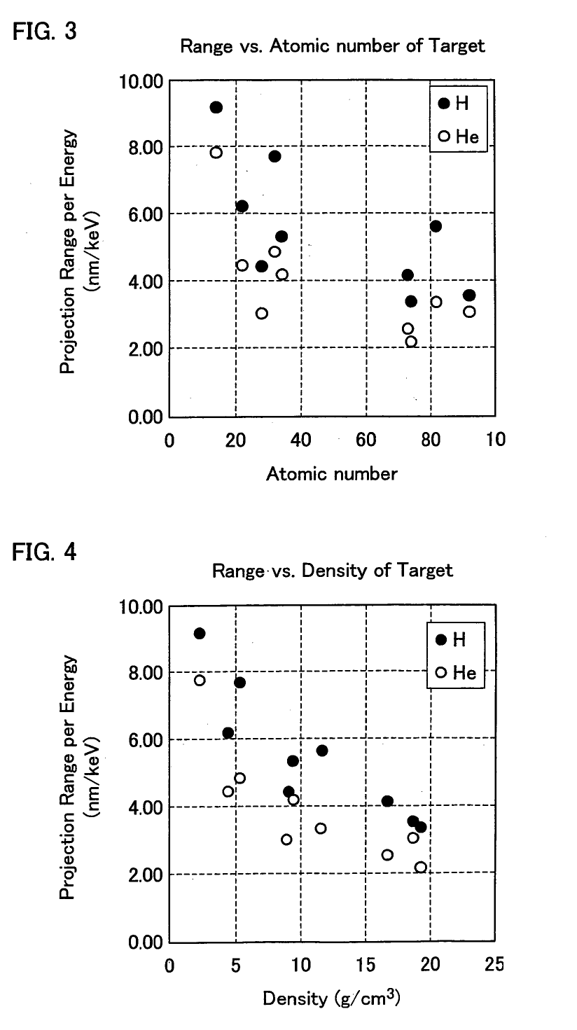

A material which can be used for the gate electrode 35 is derived from FIGS. 3 and 4. FIG. 3 shows a relationship between an average atomic number of the material and a projection range per energy of a hydrogen ion or a helium ion. FIG. 4 shows a relationship between an average density of the material and a projection range per energy of a hydrogen ion or a helium ion.

In FIGS. 3 and 4, a black dot represents a projection range of a hydrogen ion, and a white dot represents a projection range of a helium ion. Further, FIG. 3, whose vertical line represents a projection range per energy and whose horizontal line represents an average atomic number, shows Si, Ti, Ni, Ge, WSi₂, Ta, W, Pb, and U in an ascending order of their average atomic numbers. FIG. 4, whose vertical line represents a projection range per energy and whose horizontal line represents a density, shows Si, Ti, Ge, Ni, WSi₂, Pb, Ta, U, and W in an ascending order of their densities.

As can be seen from FIGS. 3 and 4, in order to achieve a projection range about ½ of or less than a projection range of Si (atomic number: 14; density: 2.33 g/cm3), which exhibits an effect of sufficiently shortening a projection range of a hydrogen ion or a helium ion, a material whose average atomic number is 28 or larger and whose density is 10 g/cm3 or higher can be used.

The gate electrode 32 is formed including the above material to sufficiently shorten a projection range of a hydrogen ion or a helium ion, and a parameter is adjusted in consideration of a thickness of the gate electrode 32, so that a peak of implantation depth of a hydrogen ion or a helium ion can be within the gate electrode. As a result, this gives an effect of preventing the transistor characteristic of the channel section from deteriorating.

Note that Y, Hf, Au, Pt, Pd, Zr, MoSi₂, CoSi₂, PtSi, PdSi, HfSi₂, TaSi₂, or ZrSi₂, in addition to those described above, can be used as a material for the gate electrode 32. For production of the gate electrode film 35, a material is selected from among these materials in consideration of a desired characteristic, resistance, and heat resistance. This is a reason why a material whose average atomic number or average density is large is used as the gate electrode film 35.

Next, a gate electrode material having been formed is patterned so as to form a gate electrode 32 by a general photolithographic process. Here, the gate electrode 32 has a line width of 0.35 μm. The other parts are also patterned so as to have a maximum line width of about 2 um or less. Further, phosphorous or boron is implanted in a self-aligning manner into a portion serving as an LDD (lightly doped drain) section 54 corresponding to a conductive type of transistor.

Further, after HALO implantation of an reverse type of impurity is conducted according to the necessity of short channel measures, and an SiO₂ film as thick as the gate electrode 32 is deposited on the gate electrode 32 by LPCVD or the like, the SiO₂ film is etched by RIE (reactive ion etching) to form side walls 37.

Next, As or BF₂ is implanted shallowly into the single crystalline silicon wafer 40 and subjected to a heat treatment at 900° C. for activation, thereby forming a source region 55 and a drain region 56. Thereafter, a surface protection film 38 with a film thickness of about 50 nm is formed. Here, an SiO₂ film was formed as the surface protection film 38.

Further, a hydrogen ion is implanted from the surface protection film 38 side perpendicularly to a surface of the substrate with an implantation energy of 80 keV and a dose of 5E16 cm⁻². At this time, interposing the SiO₂ film with a thickness of about 50 nm suppresses a channeling in the single crystalline silicon at the time of ion implantation to form a sharp implantation peak.

Note that, conventionally, an ion has been usually implanted slantwise typically at an angle of 7° with respect to a direction of a normal to the surface of the substrate in order to avoid a channeling which occurs when an ion is implanted perpendicularly. However, in this case, a nonplanar component is generated in distribution of implanted hydrogen ions or helium ions, resulting in the problem of unevenness of a peeled plane. When an ion is implanted perpendicularly to the surface of the substrate through the SiO₂ film, a nonplanar component is prevented from being generated. This improves the flatness of a surface of the single crystalline silicon film which has been cleaved and separated to be described later.

In the ion implantation, a hydrogen ion in a region where the gate electrode is formed peaks at a depth of about 250 nm below a surface of the surface protection film 38 side, and a hydrogen ion in other regions peaks at a depth of about 670 nm below an interface between the single crystalline silicon wafer 40 and the gate insulator film 36, so that a hydrogen ion implantation layer 41 is formed in the single crystalline silicon wafer 40 (Note that, at this time, a hydrogen ion implantation layer 41′ is formed in the gate electrode film 35.). A state obtained in the steps thus far described is shown in FIG. 1(a).

Next, the steps of obtaining a state shown in FIG. 1(b) will be described. The planarization film 39 is formed on the surface protection film 38 by plasma CVD with TEOS (tetra-ethoxy-silane) or TMCTS (tetra-methyl-cyclo-tetra-siloxane), and after a planarization treatment of the planarization film 39 is performed by CMP (chemical-mechanical polishing), the single crystalline silicon substrate is cut into a predetermined shape. Here, when the planarization film 39 is formed by plasma CVD with TEOS or TMCTS, the planarization film 39 has an excellent surface coating property and an excellent bonding property with respect to an insulative substrate to be described later.

Meanwhile, apart from the step of forming a main structure of the single crystalline silicon transistor on the single crystalline silicon wafer 40, an SiO₂ film 60 with a film thickness of about 50 nm is deposited by plasma CVD with a mixed gas of TEOS and O₂ on an entire surface of the insulative substrate 50 made of glass, quartz, or heat-resistant transparent resin.

Here, the SiO₂ film 60 with a thickness of 50 nm is deposited by plasma CVD with a mixed gas of TEOS and O₂ on a surface of glass (code 1737 manufactured by Corning Incorporated) provided in advance with a non-single crystalline silicon device (polycrystalline silicon TFT array and a simple scanning circuit). The non-single crystalline silicon device has been finished with a gate-producing process and a impurity-doping process before the SiO₂ film 60 is deposited.

Then, after the transparent insulative substrate 50 and the cut single crystalline silicon substrate is cleaned with an SC-1 solution for activation, the single crystalline silicon substrate is aligned in a predetermined position, and the two substrates are brought into close contact with each other for bonding. The single crystalline silicon substrate and the transparent insulative substrate 50 are bonded due to Van der Waals force, a hydrogen bond, or an electric dipole. Note that the SC-1 solution is a mixture of aqueous ammonia (NH₄OH: 30%), hydrogen peroxide (H₂O₂: 30%) and pure water (H₂O) by a ratio of 5:12:60. A state obtained in the steps thus far described is shown in FIG. 1(b).

Moreover, the steps of obtaining a state shown in FIG. 1(c) will be described. The product in the state of FIG. 1(b) is subjected to heat treatment at 400 to 600° C., at about 550° C. here. This heat treatment causes the following reaction:
Si—OH+Si—OH→Si—O—Si+H₂O.
This reaction causes the bonding of the two substrates to become a strong atomic bond, and causes hydrogen to diffuse in the hydrogen ion implantation layer 41 within the single crystalline silicon substrate, thereby generating microbubbles and cleaving and peeling an unwanted portion of the single crystalline silicon wafer 40 by the hydrogen ion implantation layer 41. Thus, single crystalline silicon is thinned to form a single crystalline silicon thin film 40′.

Note that since most of the hydrogen implanted into the gate electrode 35 desorbs at a substrate temperature of 300 to 350° C. at the time of depositing the planarization film 39, there occurs no special problem. A state obtained in the steps thus far described is shown in FIG. 1(c).

A method of forming a semiconductor device shown in FIG. 2 in a further step will be described. As shown in FIG. 1(c), a surface of the single crystalline silicon thin film 40′ which remains with a film thickness of about 550 to 670 nm after the peeling of the unwanted portion is etched with RIE to a predetermined film thickness, so that a further unwanted portion is etched away, thereby processing the single crystalline silicon thin film 40′ into an island-like shape. Thereafter, a damaged layer of the surface is etched away with isotropic plasma etching or wet etching. Here, the damaged layer is lightly etched about 10 nm by wet etching with buffer hydrofluoric acid. Thus, the single crystalline silicon thin film transistor 30 with a thickness of about 50 nm is formed on the insulative substrate 50. This is the first process.

Thereafter, a second SiO₂ film with a film thickness of about 200 nm is deposited on an entire surface of the insulative substrate 50 by plasma CVD with a mixed gas of SiH₄ and N₂O. Furthermore, an amorphous silicon film with a film thickness of about 50 nm is deposited on an entire surface of the second SiO₂ film by plasma CVD with a gas of SiH₄.

Moreover, the amorphous silicon film is irradiated with excimer laser, heated, and crystallized to form a polycrystalline silicon layer 21.

Next, in order to leave a portion serving as an active region of the device, an unwanted polycrystalline silicon film is etched away to obtain an island-like pattern.

Thereafter, the wiring metal 13 is formed and patterned after formation of an interlayer insulation film and opening of a contact hole with a well-known general material and process. Thus, a device as shown in FIG. 2, is produced in which the single crystalline silicon device 30 so transferred and the non-single crystalline silicon device 20 made of a semiconductor material by film formation are intermixed.

Note that although the amorphous silicon film is irradiated with excimer laser to form the single crystalline silicon layer 21, the step may be omitted to use the amorphous silicon film as it is. In this case, a device can also be produced in which the single crystalline silicon device 30 and the non-single crystalline silicon device 20 are intermixed. Further, although hydrogen ion is used in the example of ion implantation, a helium ion may be implanted. Furthermore, the present invention is not limited to implantation of either a hydrogen ion or a helium ion, but both a hydrogen ion and a helium ion may be implanted.

### Second Embodiment

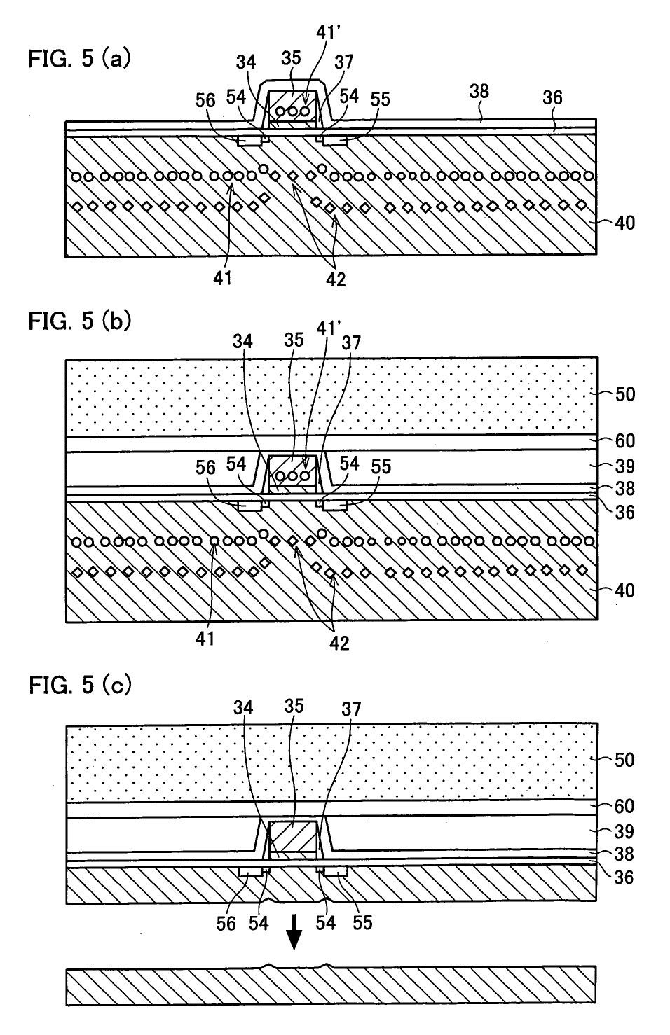

One embodiment of the present invention will be described below with reference to FIGS. 5(a) through 5(c).

A semiconductor device described in the present embodiment is a semiconductor device, including an insulative substrate provided with both a non-single crystalline silicon-based thin film transistor and a single crystalline silicon-based thin film transistor thereon, which is suitable to high performance and high sophistication. Described below as one example of the semiconductor device is a case where an active matrix substrate with a TFT is formed by using an MOS-type transistor as a non-single crystalline silicon transistor and a single crystalline silicon transistor.

Here, the semiconductor device described in the First Embodiment has as an object to prevent a transistor characteristic deterioration by preventing a hydrogen ion or a helium ion from passing through the gate electrode 32 and protecting from damage the silicon-gate insulator film interface and the single crystalline silicon under the gate electrode 32. Therefore, in a region under the gate electrode, a hydrogen ion implantation layer is not formed in the single crystalline silicon base material.

However, as described above, when the hydrogen ion implantation layer is not formed in the single crystalline silicon film under the gate electrode, there is not particularly a problem provided that the gate electrode has a sufficiently small line width. However, when the gate electrode has a large line width, there may not occur sufficient cleavage and peeling. The semiconductor device according to the Second Embodiment has a feature of solving such a problem.

Further, since an arrangement of the semiconductor device according to the Second Embodiment is about the same as that of the semiconductor device according to the First Embodiment, the same components as those described in the First Embodiment are given the same reference numerals, and detailed explanations thereof are omitted here.

A producing method of the semiconductor device according to the Second Embodiment will be described below with reference to FIGS. 5(a) to 5(c).

First, the steps of obtaining a state shown in FIG. 5(a) will be described. The single crystalline silicon wafer (single crystalline silicon substrate) 40 is cleaned by a general cleaning method (e.g., by which a natural oxide film is removed with dilute hydrofluoric acid, and a particle, organic matter, and the like are removed by SC1 and SC2 cleaning agents).

Next, a thin oxide film (not shown) for element separation and the gate insulator film 36 are formed in a predetermined region by a thermal oxidation method. The gate insulator film 36 has a thickness of 5 to 50 nm. The oxidation method is for example a pyrogenic oxidation method or an HCl oxidation method.

Next, an impurity (phosphorous or boron) for threshold control is implanted into the single crystalline silicon wafer 40.

Then, a gate electrode material with a thickness of about 200 to 400 nm is formed on the gate insulator film 36. The gate electrode material is formed of a double layer constituted of a gate electrode film 35 and a polycrystalline silicon film 34. The gate electrode film 35 includes a metal, such as tungsten, whose atomic number is large, a silicide of the metal, or both of the materials. Here, a gate electrode film with a film thickness of about 300 nm was formed on n⁺ polycrystalline silicon with a film thickness of about 50 nm by sputtering. Note that a material for the gate electrode film 35 is selected in the same way as in the First Embodiment.

Next, a gate electrode material having been formed is patterned so as to form a gate electrode 32 by a general photolithographic process. Here, the gate electrode 32 has a line width of 0.35 μm. The other portions are also patterned so as to have a maximum line width of about 2 um or less. Further, phosphorous or boron is implanted in a self-adjusting manner into a portion serving as an LDD (lightly doped drain) section 54 corresponding to a conductive type of transistor.

Further, after HALO implantation of an reverse type of impurity is conducted according to the necessity of short channel measures, and an SiO₂ film as thick as the gate electrode 32 is deposited on the gate electrode by LPCVD or the like, the SiO₂ film is etched by RIE (reactive ion etching) to form side walls 37.

Next, As or BF₂ is implanted shallowly into the single crystalline silicon wafer 40 and subjected to a heat treatment at 900° C. for activation, thereby forming a source region 55 and a drain region 56. Thereafter, a surface protection film 38 with a film thickness of about 50 nm is formed. Here, an SiO₂ film was formed as the surface protection film 38.

Further, a hydrogen ion is implanted from the surface protection film 38 side perpendicularly to a surface of the substrate with an implantation energy of 80 keV and a dose of 5E16 cm⁻². At this time, interposing the SiO₂ film suppresses a channeling even when an ion is implanted perpendicularly and improves the flatness of a surface of the single crystalline silicon film which has been cleaved and separated.

In the ion implantation, a hydrogen ion in a region where a gate electrode is formed peaks at a depth of about 250 nm below a surface of the surface protection film 38 side, and a hydrogen ion in other regions peaks at a depth of about 670 nm below an interface between the single crystalline silicon wafer 40 and the gate insulator film 36, so that a hydrogen ion implantation layer 41 is formed in the single crystalline silicon wafer 40 (Note that, at this time, a hydrogen ion implantation layer 41′ is formed in the gate electrode film 35.).

Moreover, in the semiconductor device according to the Second Embodiment, a second ion implantation is conducted with an implantation energy of about 175 keV and a dose of 2E16 cm⁻². In the second ion implantation, a hydrogen ion in a region where the gate electrode is formed peaks at a depth of about 670 nm below an interface between the single crystalline silicon wafer 40 and the gate insulator film 36, and a hydrogen ion in other regions peaks at a depth of about 1536 nm below an interface between the single crystalline silicon wafer 40 and the gate insulator film 36.

The second ion implantation is conducted in such a way that a hydrogen ion of concentration about ½ to ⅕ of that in the first ion implantation is implanted at an increased implantation energy, so that a hydrogen implantation layer is formed at a predetermined depth below the gate electrode 32 while reducing a crystal defect and a deterioration in impurity activity, both of which occur in the silicon-gate insulator film interface and the polycrystalline silicon film 34 under the gate electrode 32 due to the passage of a hydrogen ion.

Thus, in a region under the gate electrode, a hydrogen ion implantation layer 42 is formed at about the same depth as that at which a hydrogen ion of high concentration is implanted into a region except for a region where the gate electrode 32 is formed. A material for the gate electrode is selected in consideration of the characteristic, a necessary resistance, and a necessary heat-resistant property. A state obtained in the steps thus far described is shown in FIG. 5(a).

Next, the steps of obtaining a state shown in FIG. 5(b) will be described. The planarization film 39 is formed on the surface protection film 38 by plasma CVD with TEOS (tetra-ethoxy-silane) or TMCTS (tetra-methyl-cyclo-tetra-siloxane), and after a planarization treatment of the planarization film 39 is performed by CMP, the single crystalline silicon substrate is cut into a predetermined shape.

Meanwhile, apart from the step of forming a main structure of the single crystalline silicon transistor on the single crystalline silicon wafer 40, an SiO₂ film 60 with a film thickness of 50 nm is deposited by plasma CVD with a mixed gas of TEOS and O₂ on an entire surface of the insulative substrate 50 such as a glass substrate.

Here, the SiO₂ film 60 with a thickness of 50 nm is deposited by plasma CVD with a mixed gas of TEOS and O₂ on a surface of glass (code 1737 manufactured by Corning Incorporated) provided in advance with a non-single crystalline silicon device (polycrystalline silicon TFT array and a simple scanning circuit). The non-single crystalline silicon device has been finished with a gate-producing process and a impurity-doping process before the SiO₂ film 60 is deposited.

Then, after the transparent insulative substrate 50 and the cut single crystalline silicon substrate is cleaned with an SC-1 solution for activation, the single crystalline silicon substrate is aligned in a predetermined position, and the two substrates are brought into close contact with each other for bonding. The single crystalline silicon substrate and the transparent insulative substrate 50 are bonded due to Van der Waals force, a hydrogen bond, or an electric dipole. Note that the SC-1 solution is a mixture of aqueous ammonia (NH₄OH: 30%), hydrogen peroxide (H₂O₂: 30%) and pure water (H₂O) by a ratio of 5:12:60. A state obtained in the steps thus far described is shown in FIG. 5(b).

Moreover, the steps of obtaining a state shown in FIG. 5(c) will be described. The product in the state of FIG. 5(b) is subjected to heat treatment at 400 to 600° C., at about 550° C. here. This heat treatment causes the following reaction:
Si—OH+Si—OH→Si—O—Si+H₂O.
This reaction causes the bonding of the two substrates to become a strong atomic bond, and causes hydrogen to diffuse single crystalline silicon in the hydrogen ion implantation layer 41, thereby generating microbubbles and cleaving and peeling an unwanted portion of the single crystalline silicon wafer 40 between the hydrogen ion implantation layers 41 and 42. Thus, single crystalline silicon is thinned to form a single crystalline silicon thin film 40′.

Note that since most of the hydrogen implanted into the gate electrode 35 desorbs at a substrate temperature of 300 to 350° C. at the time of depositing the planarization film 39, there occurs no special problem. Further, the hydrogen ion implantation layer 42 helps cleavage and separation, so that it is possible to obtain a substantially even cleavage plane. A state obtained in the steps thus far described is shown in FIG. 5(c).

In the subsequent process, a device, as shown in FIG. 2, in which the single crystalline silicon device 30 so transferred and the non-single crystalline silicon device 20 made of a deposited semiconductor material are intermixed, can be formed in the same step as in the First Embodiment.

Note that the first hydrogen ion or helium ion implantation with high concentration and low energy may precede or follow the second hydrogen ion or helium ion implantation with low concentration and high energy. Further, in the ion implantation, a helium ion may be implanted instead of a hydrogen ion. Moreover, the present invention is not limited to implantation of either a hydrogen ion or a helium ion, but both a hydrogen ion and a helium ion may be implanted.

In an experimental case of helium ion implantations, the first ion implantation with an implantation energy of about 75 keV and the second ion implantation with an implantation energy of about 220 keV were performed at about the same concentration as in the hydrogen ion implantation. This resulted in a slightly thinner silicon film but with about the same outcome.

However, a characteristic comparison between the hydrogen ion implantation and the helium ion implantation shows that the mobility of electrons in a finally obtained TFT is high in the hydrogen ion implantation and low in the helium implantation. Further, a threshold value of an n-channel TFT tended to shift to a negative value in the hydrogen implantation, whereas there was no such tendency in the helium implantation.

### Third Embodiment

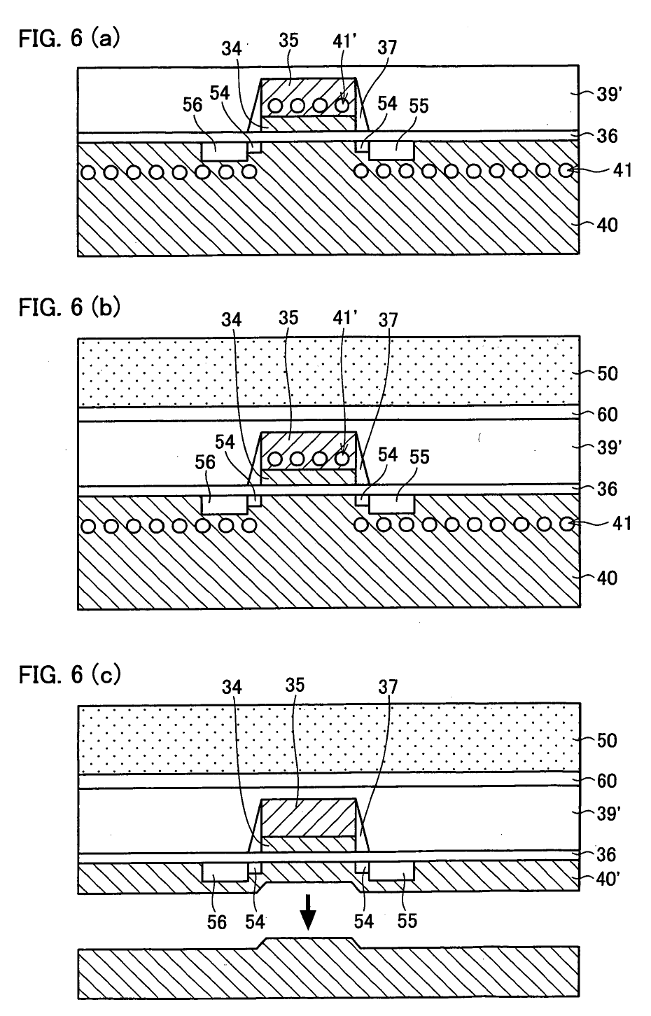

One embodiment of the present invention will be described below with reference to FIGS. 6(a) through 6(c).

A semiconductor device described in the present embodiment is a semiconductor device, including an insulative substrate provided with both a non-single crystalline silicon-based thin film transistor and a single crystalline silicon-based thin film transistor thereon, which is suitable to high performance and high sophistication. Described in below as one example of the semiconductor device is a case where an active matrix substrate with a TFT is formed by using an MOS-type transistor as a non-single crystalline silicon transistor and a single crystalline silicon transistor.

Here, in the semiconductor devices described in the First and Second Embodiments, after a hydrogen ion or a helium ion is implanted into a single crystalline silicon substrate formed with a gate electrode thereon, a planarization film is formed, and bonding of the single crystalline silicon substrate to a transparent insulative substrate is performed. Therefore, at the time of the hydrogen ion or helium ion implantation, implanted ions are not uniformly distributed due to unevenness around the gate electrode. This causes the problem of decrease in flatness of a separation plane of the silicon thin film which has been cleaved and separated. The semiconductor device according to the Third Embodiment has the feature of solving such a problem.

Further, since an arrangement of the semiconductor device according to the Third Embodiment is about the same as those of the semiconductor devices described in the First and Second Embodiments, the same components as those described in the First and Second Embodiments are given the same reference numerals, and detailed explanations thereof are omitted here.

A producing method of the semiconductor device according to the Third Embodiment will be described below with reference to FIG. 6(a) to 6(c).

First, the step of obtaining a state shown in FIG. 6(a) will be described. A single crystalline silicon wafer (single crystalline silicon substrate) 40 is cleaned by a general cleaning method (e.g., by which a natural oxide film is removed with dilute hydrofluoric acid, and a particle, organic matter, and the like are removed by SC1 and SC2 cleaning agents).

Next, a thin oxide film (not shown) for element separation and the gate insulator film 36 are formed in a predetermined region by a thermal oxidation method. The gate insulator film 36 has a thickness of 5 to 50 nm. The oxidation method is for example a pyrogenic oxidation method or an HCl oxidation method.

Then, a gate electrode material with a thickness of about 200 to 400 nm is formed on the gate insulator film 36. The gate electrode material is formed of a double layer constituted of a gate electrode film 35 and a polycrystalline silicon film 34. The gate electrode film 35 includes a metal, such as tungsten, whose atomic number is large, a silicide of the metal, or both of the materials. Here, a gate electrode film with a film thickness of about 300 nm was formed on n⁺ polycrystalline silicon with a film thickness of about 50 nm by sputtering. Note that a material for the gate electrode film 35 is selected in the same way as in the First Embodiment.

Next, a gate electrode material having been formed is patterned so as to form a gate electrode 32 by a general photolithographic process. Here, the gate electrode 32 has a line width of 0.35 μm. The other portions are also patterned so as to have a maximum line width of about 2 um or less.

Further, phosphorous or boron is implanted in a self-adjusting manner into a portion serving as an LDD (lightly doped drain) section 54 corresponding to a conductive type of transistor. Thereafter, after HALO implantation of an reverse type of impurity is conducted according to the necessity of short channel measures, and an SiO₂ film as thick as the gate electrode 32 is deposited on the gate electrode 32 by LPCVD or the like, the SiO₂ film is etched by RIE (reactive ion etching) to form side walls 37.

Next, As or BF₂ is implanted shallowly into the single crystalline silicon wafer 40 and subjected to a heat treatment at 900° C. for activation, thereby forming a source region 55 and a drain region 56. Thereafter, an insulation film 39′ with a film thickness of about 400 to 500 nm is formed by plasma CVD with TEOS or TMCTS, and a planarization treatment is performed by CMP (chemical-mechanical polishing) so that a film thickness of the SiO₂ films (gate insulator film 36 and the insulation film 39′) is made about 350 nm.

Thus, in the Third Embodiment, a surface into which a hydrogen ion or a helium ion is implanted is flattened before hydrogen ion implantation. This decreases ununiformity in distribution of implanted hydrogen ions of high concentration, thus improving the flatness of the silicon thin film being cleaved and separated.

Next, a hydrogen ion is implanted perpendicularly to a surface provided with the insulation film 39′ with an implantation energy of 60 keV and a dose of 5E16 cm⁻². At this time, interposing the insulation film 39′ suppresses a channeling even when an ion is implanted perpendicularly and improves the flatness of a surface of the single crystalline silicon film which has been cleaved and separated.

Here, a hydrogen ion in a region where the gate electrode is formed peaks at a depth of about 190 nm below a surface of the insulation film 39′, and a hydrogen ion in other regions peaks at a depth of about 200 nm below an interface between the single crystalline silicon wafer 40 and the gate insulator film 36 to form the hydrogen ion implantation layer 41. No hydrogen ion is implanted into the channel section under the gate electrode.

A state obtained in the steps thus far described is shown in FIG. 6(a).

Next, the steps of obtaining a state shown in FIG. 6(b) will be described. The single crystalline silicon substrate as shown in FIG. 6(a) is cut into a predetermined shape.

Meanwhile, apart from the step of forming a main structure of the single crystalline silicon transistor on the single crystalline silicon wafer 40, an SiO₂ film 60 with a film thickness of about 50 nm is deposited by plasma CVD with a mixed gas of TEOS and O₂ on an entire surface of the insulative substrate 50 such as a glass substrate.

Here, the SiO₂ film 60 with a thickness of 50 nm is deposited by plasma CVD with a mixed gas of TEOS and O₂ on a surface of glass (code 1737 manufactured by Corning Incorporated) provided in advance with a non-single crystalline silicon device (polycrystalline silicon TFT array and a simple scanning circuit). The non-single crystalline silicon device has been finished with a gate-producing process and a impurity-doping process before the SiO₂ film 60 is deposited.

Then, after the transparent insulative substrate 50 and the cut single crystalline silicon substrate is cleaned with an SC-1 solution for activation, the single crystalline silicon substrate is aligned in a predetermined position, and the two substrates are brought into close contact with each other for bonding. Note that the SC-1 solution is a mixture of aqueous ammonia (NH₄OH: 30%), hydrogen peroxide (H₂O₂: 30%) and pure water (H₂O) by a ratio of 5:12:60. A state obtained in the steps thus far described is shown in FIG. 6(b).

Moreover, the steps of obtaining a state shown in FIG. 6(c) will be described. The product in the state of FIG. 6(b) is subjected to heat treatment at 400 to 600° C., at about 550° C. here. This heat treatment causes the following reaction:
Si—OH+Si—OH→Si—O—Si+H₂O.
This reaction causes the bonding of the two substrates to become a strong atomic bond, and causes hydrogen to diffuse the single crystalline silicon in the hydrogen ion implantation layer 41, thereby generating microbubbles and cleaving and peeling an unwanted portion of the single crystalline silicon wafer 40 by the hydrogen ion implantation layers 41. Thus, single crystalline silicon is thinned to form a single crystalline silicon thin film 40′. A state obtained in the steps thus far described is shown in FIG. 6(c).

Note that since most of the hydrogen implanted into the gate electrode 35 desorbs at a substrate temperature of 300 to 350° C. at the time of depositing the planarization film 39, there occurs no special problem.

In the subsequent process, a device, as shown in FIG. 2, in which the single crystalline silicon device 30 so transferred and the non-single crystalline silicon device 20 made of a deposited semiconductor material are intermixed, can be formed in the same step as in the First embodiment.

Note that although only one step of implanting a hydrogen ion of high concentration with single energy is conducted in the foregoing description of the Third Embodiment as with the First Embodiment, two steps of ion implantation may be conducted with ion concentration and implantation energy varied in each step as with the Second Embodiment. Needless to say, two steps of ion implantations bring more excellent flatness of a silicon film which has been cleaved and separated.

Further, in the First to Third Embodiments, it is preferable that a pattern of the gate electrode 32 in the single crystalline silicon thin film transistor 30 include no continuous pattern of 2 μm or more per side in lateral and longitudinal directions.

That is, an area under the continuous region of about 2 μm or more in the gate pattern becomes a region where a hydrogen ion or the like is not implanted or a region where a hydrogen ion concentration is low, which may cause the problem that the silicon film in part, corresponding to the above region, is cleaved poorly, separated into two with a hollow on its surface, or is not separated into two at all. On the contrary, with a gate pattern including a continuous region of about less than 2 μm per side in both of the two directions, avoidance of the above problem and an excellent separation can be realized for a slight lateral cleavage and a laterally distributed ion. As a concrete example, a hole of about 2 to 5 μm in diameter may be provided in a large continuous pattern so that the gate pattern has no continuous pattern of about 2 μm or more per side.

As described above, the semiconductor device of the present invention is arranged so that a gate electrode of a single crystalline silicon thin film transistor is made of a material including (i) an element whose average atomic number is 28 or larger, (ii) an element whose density is 10 g/cm³ or higher, (iii) a compound containing the element (i), or (iv) a compound containing the element (ii), the single crystalline silicon thin film transistor having a source, a drain, and a channel region provided in single crystalline silicon.

Alternatively, the semiconductor device of the present invention is a semiconductor device including an insulative substrate and a thin film device formed thereon, wherein: a non-single crystalline silicon thin film transistor and a single crystalline silicon thin film are provided together, the non-single crystalline silicon thin film transistor having a source, a drain, and a channel region provided in non-single crystalline silicon, the single crystalline silicon thin film transistor having a source, a drain, and a channel region provided in single crystalline silicon, and a gate electrode of the single crystalline silicon thin film transistor is made of a material including (i) an element whose average atomic number is 28 or larger, (ii) an element whose density is 10 g/cm³ or higher, (iii) a compound containing the element (i), or (iv) a compound containing the element (ii).

With the foregoing arrangement, a hydrogen ion or a helium ion can be prevented from passing through a gate layer, so that a silicon-gate insulator film interface and the channel region under the gate electrode are protected from damage.

Note that the semiconductor device of the present invention is desired to include no continuous pattern of 2 μm or more per side in lateral and longitudinal directions. This is because it is considered that with a gate pattern including a continuous region of about less than 2 μm per side in both of the two directions, cleavage failure in an area under the gate electrode can be avoided for a slight lateral cleavage and a laterally distributed ion.

Further, it is preferable that the semiconductor device of the present invention be a TFT liquid crystal display device or an organic EL display device.

With the foregoing arrangement, the present invention can be applied very suitably in producing a TFT liquid crystal display device or an organic EL display device having a substrate including a display panel section and a drive circuit section integrated onto. This is because circuit performance of a display device can be improved in an arrangement where a switching element and the like in the display section are realized by a thin film transistor formed of a non-single crystalline silicon thin film, and the drive circuit section and the like are realized by a thin film transistor formed of a single crystalline silicon thin film.

Further, it is preferable that the semiconductor device of the present invention be arranged so that the insulative substrate has permeability in a visible light wavelength band.

Further, as described above, a method of the present invention for producing a semiconductor device is a method for producing a semiconductor substrate including a single crystalline silicon substrate and a gate electrode formed thereon with a gate insulator film interposed therebetween, the method including the steps of: forming a surface protection film on a region serving as a transistor including the gate electrode; and implanting a hydrogen ion and/or a helium ion of predetermined concentration into the single crystalline silicon substrate, wherein: a combination of conditions an implantation energy of a hydrogen ion and/or a helium ion, a material for the gate electrode, and a film thickness of the surface protection film is set so that a projection range of a hydrogen ion and/or a helium ion is equal to or less than a total film thickness of the gate electrode and the surface protection film in a region where the gate electrode is formed, and so that a projection range of a hydrogen ion and/or a helium ion is more than the total film thickness of the gate electrode and the surface protection film in a region where the gate electrode is not formed.

With the foregoing arrangement, when a hydrogen ion and/or a helium ion are/is implanted into a silicon layer, a projection range of a hydrogen ion and/or a helium ion becomes equal to or less than a total film thickness of the gate electrode and the surface protection film in a region where the gate electrode is formed. This prevents a transistor characteristic deterioration caused when a hydrogen ion or a helium ion is implanted into a channel section (i.e., a section under a gate electrode) of a transistor.

Note that implantation of a hydrogen ion and/or a helium ion into the single crystalline silicon substrate is not limited to implantation of either a hydrogen ion or a helium ion, but also includes implantation of both a hydrogen ion and a helium ion.

Further, as described above, another method of the present invention for producing a semiconductor device is a producing method of a semiconductor substrate including a single crystalline silicon substrate and a gate electrode formed thereon with a gate insulator film interposed therebetween, the method including the steps of: forming a surface protection film on a region serving as a transistor including the gate electrode; and implanting a hydrogen ion and/or a helium ion of predetermined concentration into a single crystalline silicon substrate more than once, the hydrogen ion and/or helium ion implantation step including: a first implantation step in which a combination of conditions of an implantation energy of a hydrogen ion and/or a helium ion, a material for the gate electrode, and a film thickness of the surface protection film is determined so that a projection range of a hydrogen ion and/or a helium ion is equal to or less than a total film thickness of the gate electrode and the surface protection film in a region where the gate electrode is formed, and so that a projection range of a hydrogen ion and/or a helium ion is more than the total film thickness of the gate electrode and the surface protection film in a region where the gate electrode is not formed; and a second implantation step of implanting a hydrogen ion and/or a helium ion at lower ion implantation concentration than in the first implantation step, wherein an implantation energy is set so that, in the region where the gate electrode is formed, an implantation peak position of a hydrogen ion and/or a helium ion passing through the gate electrode and the gate insulator film becomes equal to an implantation peak position of a hydrogen ion and/or a helium ion passing through the surface protection film and gate insulator film at the time of ion implantation in the first implantation step.

With the foregoing arrangement, when a hydrogen ion and/or a helium ion are/is implanted into a silicon layer in the first ion implantation step, a projection range of a hydrogen ion and/or a helium ion becomes equal to or less than a total film thickness of the gate electrode and the surface protection film in a region where the gate electrode is formed. This prevents a transistor characteristic deterioration caused when a hydrogen ion or a helium ion is implanted into a channel section (i.e., a section under a gate electrode) of a transistor.

Further, in the second ion implantation step, an implantation peak position of an ion implanted into an area under the gate electrode becomes equal to that of a hydrogen ion and/or a helium ion implanted through the surface protection film and a gate oxide film in the first ion implantation step. This helps cleave and separate the area under of the gate electrode, thus improving the flatness of the silicon film which has been cleaved and separated.

Note that the first ion implantation step may precede or follow the second ion implantation step.

Further, as described above, a further method of the present invention for producing a semiconductor device is a method for producing a semiconductor substrate including a single crystalline silicon substrate and a gate electrode formed thereon with a gate insulator film interposed therebetween, the method including the steps of: forming a planarization insulator film thicker than the gate electrode on a region serving as a transistor including the gate electrode; and implanting a hydrogen ion and/or a helium ion of predetermined concentration into the single crystalline silicon substrate after planarization of the planarization insulator film, wherein: a combination of conditions of an implantation energy of a hydrogen ion and/or a helium ion, a material for the gate electrode, and a film thickness of the planarization insulator film is set so that a projection range of a hydrogen ion and/or a helium ion is equal to or less than a total film thickness of the gate electrode and the planarization insulator film in a region where the gate electrode is formed and so that a projection range of a hydrogen ion and/or a helium ion is more than the total film thickness of the gate electrode and the planarization insulator film in a region where the gate electrode is not formed.

With the foregoing arrangement, when a hydrogen ion and/or a helium ion are/is implanted into a silicon layer, a projection range of a hydrogen ion and/or a helium ion becomes equal to or less than a total film thickness of the gate electrode and the planarization insulator film in a region where the gate electrode is formed. This prevents a transistor characteristic deterioration caused when a hydrogen ion or a helium ion is implanted into a channel section of a transistor. Further, planarization of a perimeter of the gate electrode before ion implantation decreases ununiformity in distribution of implanted hydrogen ions of high concentration, thus improving the flatness of the silicon thin film being cleaved and separated.

Further, it is preferable that the semiconductor device of the present invention be arranged so that the planarization insulator film is made of SiO₂ deposited by plasma CVD with TEOS or TMCTS.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

1. A semiconductor device, wherein:
a gate electrode of a single crystalline silicon thin film transistor is made of a material including (i) an element whose average atomic number is 28 or larger, (ii) an element whose density is 10 g/cm³ or higher, (iii) a compound containing the element (i), or (iv) a compound containing the element (ii), the single crystalline silicon thin film transistor having a source, a drain, and a channel region provided in single crystalline silicon.

2. A semiconductor device including an insulative substrate and a thin film device formed thereon, wherein:
a non-single crystalline silicon thin film transistor and a single crystalline silicon thin film are provided together, the non-single crystalline silicon thin film transistor having a source, a drain, and a channel region provided in non-single crystalline silicon, the single crystalline silicon thin film transistor having a source, a drain, and a channel region provided in single crystalline silicon, and
a gate electrode of the single crystalline silicon thin film transistor is made of a material including (i) an element whose average atomic number is 28 or larger, (ii) an element whose density is 10 g/cm³ or higher, (iii) a compound containing the element (i), or (iv) a compound containing the element (ii).

3. The semiconductor device according to claim 2, wherein:
the insulative substrate has permeability in a visible light wavelength band.

4. The semiconductor device according to claim 2, being a TFT liquid crystal display device or an organic EL display device.

5. The semiconductor display device according to claim 1, wherein:
the element is metal or semimetal.

6. The semiconductor display device according to claim 2, wherein:
the element is metal or semimetal.

7. The semiconductor display device according to claim 1, wherein:
the gate electrode includes a layer made of tungsten or tungsten silicide.

8. The semiconductor display device according to claim 2, wherein:
the gate electrode includes a layer made of tungsten or tungsten silicide.

9. A producing method of a semiconductor substrate including a single crystalline silicon substrate and a gate electrode formed thereon with a gate insulator film interposed therebetween,
the method comprising the steps of:
forming a surface protection film on a region serving as a transistor including the gate electrode; and
implanting a hydrogen ion and/or a helium ion of predetermined concentration into the single crystalline silicon substrate,
wherein:
a combination of conditions an implantation energy of a hydrogen ion and/or a helium ion, a material for said gate electrode, and a film thickness of said surface protection film is set so that a projection range of a hydrogen ion and/or a helium ion is equal to or less than a total film thickness of said gate electrode and said surface protection film in a region where said gate electrode is formed, and so that a projection range of a hydrogen ion and/or a helium ion is more than the total film thickness of said gate insulator film and said surface protection film in a region where said gate electrode is not formed.

10. A producing method of a semiconductor substrate including a single crystalline silicon substrate and a gate electrode formed thereon with a gate insulator film interposed therebetween,
the method comprising the steps of:
forming a surface protection film on a region serving as a transistor including said gate electrode; and
implanting a hydrogen ion and/or a helium ion of predetermined concentration into a single crystalline silicon substrate more than once,
said hydrogen ion and/or helium ion implantation step including:
a first implantation step in which a combination of conditions of an implantation energy of a hydrogen ion and/or a helium ion, a material for the gate electrode, and a film thickness of the surface protection film is determined so that a projection range of a hydrogen ion and/or a helium ion is equal to or less than a total film thickness of said gate electrode and said surface protection film in a region where said gate electrode is formed, and so that a projection range of a hydrogen ion and/or a helium ion is more than the total film thickness of said gate insulator film and said surface protection film in a region where said gate electrode is not formed; and
a second implantation step of implanting a hydrogen ion and/or a helium ion at lower ion implantation concentration than in said first implantation step, wherein an implantation energy is set so that, in the region where said gate electrode is formed, an implantation peak position of a hydrogen ion and/or a helium ion passing through the gate electrode and the gate insulator film becomes equal to an implantation peak position of a hydrogen ion and/or a helium ion passing through said surface protection film and gate insulator film at the time of ion implantation in said first implantation step.

11. A producing method of a semiconductor substrate including a single crystalline silicon substrate and a gate electrode formed thereon with a gate insulator film interposed therebetween,
the method comprising the steps of:
forming a planarization insulator film thicker than said gate electrode on a region serving as a transistor including said gate electrode; and
implanting a hydrogen ion and/or a helium ion of predetermined concentration into the single crystalline silicon substrate after planarization of said planarization insulator film,
wherein:
a combination of conditions of an implantation energy of a hydrogen ion and/or a helium ion, a material for said gate electrode, and a film thickness of said planarization insulator film is set so that a projection range of a hydrogen ion and/or a helium ion is equal to or less than a total film thickness of said gate electrode and said planarization insulator film in a region where said gate electrode is formed and so that a projection range of a hydrogen ion and/or a helium ion is more than the total film thickness of said gate insulator film and said planarization insulator film in a region where said gate electrode is not formed.

12. The method according to claim 11, wherein:
said planarization insulator film is made of SiO₂ deposited by plasma CVD with TEOS or TMCTS.

13. A producing method of a semiconductor device, comprising the steps of:
cutting into a predetermined shape a semiconductor substrate produced by the producing method according to claim 9;
cleaning the cut semiconductor substrate and an insulative substrate for activation;
bringing said semiconductor substrate and said insulative substrate into close contact with each other for bonding; and
by heat treatment, cleaving and separating a single crystalline silicon substrate of said semiconductor substrate at an implantation peak position of a hydrogen ion and/or a helium ion in the single crystalline silicon substrate, so as to thin the semiconductor substrate.

14. A producing method of a semiconductor device, comprising the steps of:
cutting into a predetermined shape a semiconductor substrate produced by the producing method according to claim 10;
cleaning the cut semiconductor substrate and an insulative substrate for activation;
bringing said semiconductor substrate and said insulative substrate into close contact with each other for bonding; and
by heat treatment, cleaving and separating a single crystalline silicon substrate of said semiconductor substrate at an implantation peak position of a hydrogen ion and/or a helium ion in the single crystalline silicon substrate, so as to thin the semiconductor substrate.

15. A producing method of a semiconductor device, comprising the steps of:
cutting into a predetermined shape a semiconductor substrate produced by the producing method according to claim 11;
cleaning the cut semiconductor substrate and an insulative substrate for activation;
bringing said semiconductor substrate and said insulative substrate into close contact with each other for bonding; and
by heat treatment, cleaving and separating a single crystalline silicon substrate of said semiconductor substrate at an implantation peak position of a hydrogen ion and/or a helium ion in the single crystalline silicon substrate, so as to thin the semiconductor substrate.
